(19) United States
(12) Patent Application Publication
(10) Pub. No.: US 2011/0284061 A1
(43) Pub. Date: Nov. 24, 2011

(54) PHOTOVOLTAIC CELL AND METHODS FOR PRODUCING A PHOTOVOLTAIC CELL

(75) Inventors: Milan Vanecek, Praha 4-modrany (CZ); Johannes Meier, Corcelles (CH); Ulrich Kroll, Corcelles (CH)

(73) Assignees: FYZIKALNI USTAV AV CR, V.V.I., Praha 8 (CZ); OERLIKON TRADING AG, TRUBBACH, Trubbach (CH)

(21) Appl. No.: 12/933,205

(22) PCT Filed: Mar. 20, 2009
(86) PCT No.: PCT/IB2009/051186

§ 371 Date: Dec. 7, 2010

Related U.S. Application Data
(60) Provisional application No. 61/038,553, filed on Mar. 21, 2008.
(60) Provisional application No. 61/154,160, filed on Feb. 20, 2009.

(51) Int. Cl. H01L 31/0236; H01L 31/06; H01L 31/0216; H01L 31/0232

(52) U.S. Cl. 136/255; 136/256; 438/72; 257/E31.119

(57) ABSTRACT

A photovoltaic cell (10) is provided which includes a substrate carrier (11), a first transparent conductive layer (12) positioned on the substrate carrier (11) comprising a plurality of discrete transparent conductive protruding regions (13) or a plurality of discrete indentations. A silicon layer (14) comprising a charge separating junction covers the first transparent conductive layer (12) and the plurality of discrete transparent conductive protruding regions (13) or the plurality of discrete indentations and a second transparent conductive layer (15) is positioned on the silicon layer (14).

The present invention relates to a thin film silicon photovoltaic cell, in particular a thin film silicon solar cell, which may be a single or multi-junction device.

Presently, amorphous silicon solar cells are industrially produced in large quantities by different producers. However, there is a limit for their absolute efficiency when converting solar energy into electricity. Solar cells nowadays are typically deposited as a thin amorphous film (around 300 nm of thickness) on a respective substrate; the efficiency of such solar cells is typically below 6%.

The current generated by the solar cell can be increased by increasing the cell thickness, thus allowing more light to be absorbed. Due to the so called Staebler-Wronski effect (SWE), however, this approach does not yield higher efficiency in a long term timescale due to light-created defects in the amorphous Si absorber layer. The SWE can be reduced by introduction of nanocrystallites into the amorphous part, as described e.g. in U.S. patent application Ser. No. 11/744,918 by S. Guha et al. However, defect formation is not completely avoided.

Hence, a present strategy is to increase the light path in a thinner absorber (thickness typically in the 200-300 nm range) by light scattering at nano-rough interfaces and subsequently light trapping in the absorber layer. This process has also some inherent limitations in typical p-i-n cell structures as described and modelled in the scientific literature.

Experimental data show that reducing the amorphous absorber thickness below 200 nm results in increased stability against light soaking, as described in S. Benagli et al., Proceedings of 21st European Photovoltaic Solar Energy Conference, p. 1719, (Dresden 2006). Nevertheless not sufficient light is being absorbed in such thin cells, as it can be modeled by the optical model described in J. Appl. Phys. 96 (2004) 5329 by J. Springer, A. Poruba and M. Vanecek.

Therefore, at present there is a strong focus on tandem or triple junction solar cells with a thin amorphous layer as the absorber of a p-i-n or n-i-p top cell. The efficiency can be increased this way but the thin amorphous layer, necessary for a good collection of photogenerated carriers remains a limiting factor. Another drawback is a relatively thick bottom layer (for example microcrystalline silicon), which again increased the demand for a high electronic quality of the microcrystalline absorber in order to collect all photogenerated carriers.

It is, therefore, desirable to provide a photovoltaic cell which has an increased stable efficiency and has a high electronic quality.

A photovoltaic cell is provided which comprises a substrate carrier and a first transparent conductive layer positioned on the substrate carrier comprising a plurality of discrete transparent conductive protruding regions or a plurality of discrete indentations. A silicon layer comprising a charge separating junction or junctions in the case of p-i-n cells or p-i-n cells covers the first transparent conductive layer and the plurality of discrete transparent conductive protruding regions or the plurality of discrete indentations. A second transparent conductive layer is positioned on the silicon layer.

Light impinges the substrate in a perpendicular direction to the major surface of the substrate. Due to the protruding regions or indentations of the first transparent conductive layer, the silicon layer and the charge separating junction has a folded structure which follows the contour of the protruding regions or indentations of the first transparent layer.

This results in the photovoltaic cell being optically thicker than a planar arrangement of the layers. However, transport of the photogenerated charge between the electrodes the cell is electrically thin as the thickness of the cell overall is not increased. An increased proportion of the photogenerated charge carriers can be collected in p-i-n type structure even in the less advantageous case of the light-soaked amorphous silicon or a higher defect density nano- and microcrystalline silicon.

The substrate carrier may be a superstrate. The term superstrate refers to a solar cell configuration where the glass substrate is not only used as supporting structure but also as window for the illumination and as part of the encapsulation. During operation the glass is “above” the actual solar cell formed by the two transparent conductive layers and the silicon layer with the charge separating junction or junctions.

The term discrete is used herein to denote that the protruding regions or indentations are spaced at a distance from their immediate neighbour.

In an embodiment, the charge separating junction has a contour which is conformal to the contour of the first transparent conductive layer. Therefore, the contour of the junction can be controlled by controlling the form of the surface of the first transparent conductive layer.

Conformal is defined herein to describe a layer which has a contour which generally matches or corresponds to the contour of the underlying surface on which the layer is positioned.

In an embodiment, the charge separating junction comprises alternately arranged generally vertical and generally horizontal regions. The protruding regions or indentations may, for example, be generally cylindrical to provide a charge separating junction having this contour.

In further embodiments, the silicon layer and/or the second transparent conductive layer are positioned conformally on the first transparent conductive layer. The conformity of the layers may be achieved by selecting an appropriate deposition method and/or the conditions used to deposit the layers.

In an embodiment, the plurality of discrete transparent conductive protruding regions or the plurality of discrete indentations are around the border line nanoscale-microscale. This has the advantage that the photogenerated charge carriers can be more efficiently collected and the efficiency of the photovoltaic cell can be further improved

Nanoscale is defined herein as a structure having at least one dimension which is less than 200 nm. For example, a cylindrical protruding region having a diameter of 150 nm and a height of 500 nm is defined herein as nanoscale as the diameter is less than 200 nm even though the height should be greater than 200 nm. For example, a cylindrical protruding region having a diameter of 500 nm is defined here as microscale, close to the border line with nanoscale.

In an embodiment, the plurality of transparent conductive protruding regions or indentations extend generally perpendicular to a major plane of the substrate carrier and in particular generally parallel to the direction of the impinging light. This further increases the efficiency of the photovoltaic cell.

In an embodiment, the plurality of transparent conductive protruding regions or the plurality of indentations are arranged in an approximately ordered array. Such an arrangement can increase the density of the folded charge separating junction. The ordered array may be a hexagonal closed packed arrangement, for example.

The transparent conductive protruding regions or the plurality of indentations may each have a generally elongate form and may have the form of one of more of a pillar, a cone with or without a tip or a pyramid with or without the tip or a hemisphere.

In an embodiment, the substrate carrier comprises a plurality of nanoscale protruding regions. In this embodiment, the first transparent conductive layer is positioned conformally on the substrate carrier and the silicon layer is positioned conformally on the first transparent conductive layer. Depending on the material used for the substrate, it may be easier and more cost effective to structure the material of the substrate carrier than the material of the first transparent layer. Many glasses, for example, can be simply and reliably structured by etching on at the nanometer scale.

In an embodiment, the spacing of the protruding regions or indentations and the thickness of the overlying layers is such that the second transparent conductive layer fills regions between the protruding regions of the silicon layer.

The charge separating junction of the silicon layer may be one of a p-n junction and a p-i-n junction.

In an embodiment, the silicon layer comprises a p-type semiconductor layer, an intrinsic layer and a n-type semiconductor layer of amorphous, nanocrystalline, micro-crystalline or recrystallized polycrystalline silicon.

The photovoltaic cell may also be a multi-junction device as well as a single junction device. In an embodiment, the silicon layer comprises a first deposited p-i-n stack with an absorber bandgap larger than the absorber bandgap of a secondly deposited p-i-n stack. The use of different bandgaps enables a higher conversion efficiency of the impinging light to electricity.

The first p-i-n stack may comprise amorphous silicon and the second p-i-n stack comprises nanocrystal line or microcrystalline silicon.

In a further embodiment, the photovoltaic cell includes three p-i-n-junctions. The silicon layer comprises a first p-i-n stack with a first absorber bandgap, a second p-i-n stack having a second absorber bandgap and a third p-i-n stack having a third absorber bandgap, wherein the second absorber bandgap is larger than the third absorber bandgap and the first absorber bandgap is larger than the second absorber bandgap.

For transparent substrates such as glass, the p-type semiconductor layer is positioned on the first transparent conductive layer, the intrinsic layer is positioned on the p-type semiconductor layer and the n-type semiconductor layer is positioned on the intrinsic layer.

If the photovoltaic cell includes a transparent substrate, it may further comprise a reflective layer positioned on the second transparent conductive layer. The reflective layer may comprises a white pigmented dielectric reflective media.

In a further embodiment, the substrate carrier is non-transparent to the impinging light. The substrate carrier may comprise metal or plastic. In these embodiments, the order of the positively and negatively-charged layers of the silicon absorber layer is reversed in comparison to that described above for transparent substrate carriers. Therefore, the n-type semiconductor layer is positioned on the substrate, the intrinsic layer is positioned on the n-type semiconductor layer and the p-type semiconductor layer is positioned on the intrinsic layer. The photovoltaic cell may also further comprise a conductive layer comprising metal positioned on the substrate carrier between the substrate carrier and the first transparent conductive layer.

Methods of fabricating a photovoltaic cell are also provided. In a method a substrate carrier is provided, a first transparent conductive layer is deposited onto the substrate carrier and a plurality of discrete transparent conductive protruding regions on the first transparent conductive layer or forming a plurality of discrete indentations in the first transparent conductive layer is formed. A silicon layer comprising a charge separating junction is deposited onto the first transparent conductive layer and the plurality of protruding regions or the plurality of indentations and a second transparent conductive layer is deposited on the silicon layer.

The first transparent conductive layer has an undulating surface profile. This undulating surface profile can be transferred to the overlying silicon layer and the charge separation junction to provide a photovoltaic ell with an undulating or folded junction.

In an embodiment, a structured layer of transparent conductive material may be deposited directly. However, in further embodiment, a closed layer of a transparent conductive material is deposited and then regions selectively removed to produce the plurality of discrete transparent conductive protrusions or the plurality of discrete indentations. The form and dimensions of the protruding regions or indentations may be more closely defined using a removal method.

In an embodiment, a plurality of discrete metal islands are deposited on the closed layer and regions outside of the metal islands are removed by selective etching to produce a plurality of discrete protruding regions of transparent conductive material.

In a further embodiment, a patterned resist layer is produced on the closed layer and discrete indentations etched in the closed transparent conductive layer.

If an etching method is used to remove regions of the first transparent conductive layer, the depth of the indentations or the height of the protruding regions is controlled by the etching time.

In a further embodiment, the depth of the indentations or the height of the protruding regions is controlled by the choice of the material and structure of the first transparent conductive layer. A first closed layer of a first transparent conductive material having a first composition is deposited and a second closed layer of transparent conductive material having a second composition is deposited, the second closed layer is selectively etched away until the boundary between the first and second layers is reached.

The first transparent conductive layer may structured by reactive ion etching, wet chemical etching or photolithography to produce the plurality of discrete protruding regions of a transparent conductive material or the plurality of discrete indentations.

In a further embodiment, the first transparent conductive layer is structured by electron beam lithography to produce the plurality of discrete protruding regions of a transparent conductive material or lithography is used to produce the plurality of discrete indentations.

The plurality of protruding regions or the plurality of indentations have be structured so that they each have the form of one or more of a pillar, a pyramid, a hemisphere or a cone.

In an embodiment, the silicon layer is deposited conformally onto the first transparent conductive layer and the plurality of protruding regions or the plurality of indentations. The contour of the silicon layer and of the charge separating junction is largely determined by the contour of the outer surface of the first transparent layer so that the length of the junction can be increased.

The second transparent conductive layer may also be deposited conformally onto the silicon layer or non-conformally to fill regions between adjacent protruding regions or fills the indentations.

In an embodiment, three sub-layers are deposited to form the silicon layer and a p-i-n or p-i-n charge separating junction. The doping type, i.e. positively charged, p-type, or negatively charged, n-type, or intrinsically doped, i-type, is adjusted during deposition so as to provide the desired order of the three sub-layers.

In an embodiment, the substrate carrier is structured to produce a plurality of discrete protruding regions or a plurality of discrete indentations. The first transparent layer may then deposited onto the structured substrate carrier to produce a first transparent conductive layer of differing thickness and a plurality of discrete protruding regions or a plurality of discrete indentations. The first transparent conductive layer may be deposited conformally on the substrate carrier, to produce discrete protruding regions or indentations of a first transparent conductive material. The silicon layer may then be deposited conformally on the first transparent conductive layer.

In embodiments in which the substrate carrier is glass, a further reflective layer is deposited onto the second transparent conductive layer.

More specifically the present invention focuses on increasing the short-circuit-current that can be drawn from photovoltaic devices via an increased (extended) light path (“optically thick”) in these silicon based thin layer structures while keeping the charge transport path short enough (“electrically thin”), hence fulfilling a strong requirement for the electronic quality of the PV-cell's absorber layer. Said electronic quality is known to be negatively effected for example by the so called Staebler-Wronski effect in amorphous silicon or by increased deposition rates in microcrystalline silicon.

The invention teaches to increase the optical thickness of the amorphous absorber layer to more than 500 nm while keeping the distance between the electrodes below about 200 nm, which is possible due to the special geometry of the solar cell. The underlying general principle is that the optical thickness, i.e. the thickness in a direction perpendicular to the substrate, is distinctly larger than the electrical thickness, i.e. the carrier collection path between the electrodes. Light scattering and light trapping in the structure according to embodiments of the present application further increases the optical path of weakly absorbed light. Therefore two previously contradicting goals can be combined and simultaneously more efficient and more stable amorphous silicon solar cells can be provided.

This concept is even more advantageous for tandem or triple junction cells. Here, the dimensions used in the amorphous silicon solar cell are enlarged, it means longer pillars with a larger spacing between them or deeper and wider indentations. Again, a higher current is drawn from the device and current matching between the cells in the tandem or triple junction is obtained with a thinner lower bandgap cell, because on a substantial part of the cell these layers run in parallel. This is an important advantage allowing a shorter deposition time for the lower bandgap cell. The previous necessity to make the low bangap cell thick for current matching and high cell efficiency has been a limiting factor for cost effective tandem cells.

Embodiments are now described with reference to the accompanying drawings.

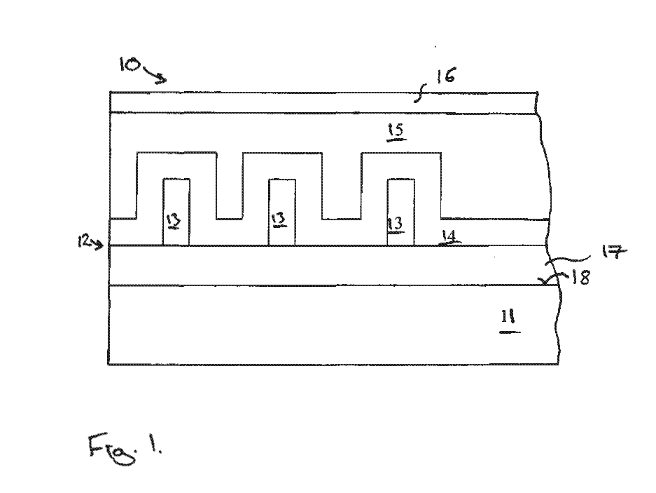

FIG. 1 illustrates a cross-sectional view of a photovoltaic cell according to a first embodiment,

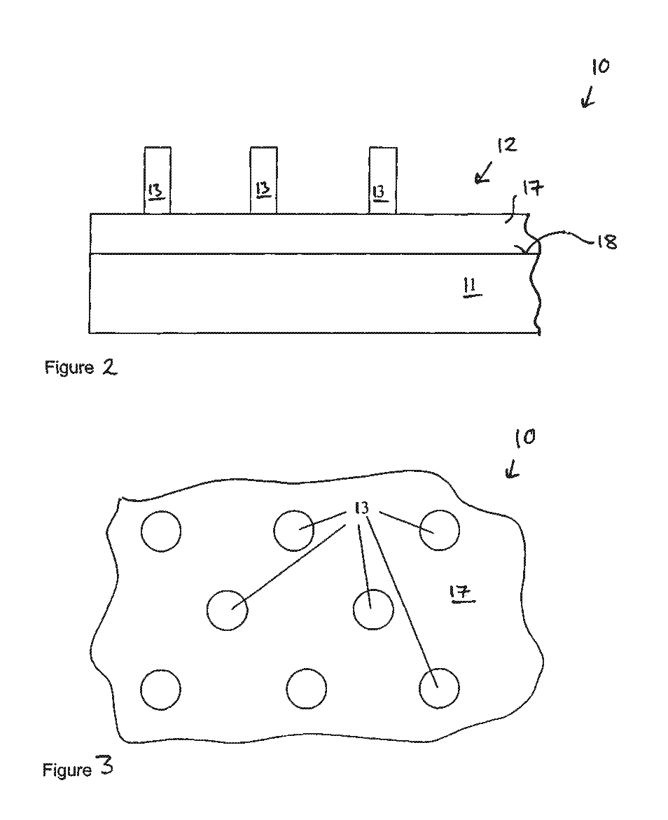

FIG. 2 illustrates a substrate with a plurality of transparent conductive pillars,

FIG. 3 illustrates a top view of the substrate of FIG. 2,

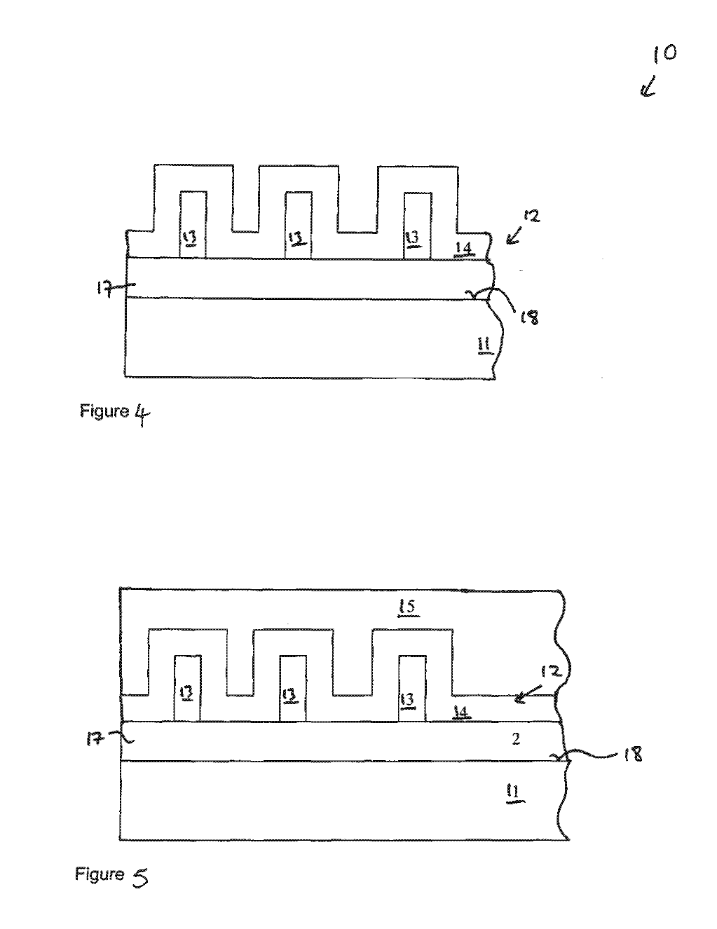

FIG. 4 illustrates the deposition of a thin film silicon photovoltaic structure onto the substrate of FIG. 2,

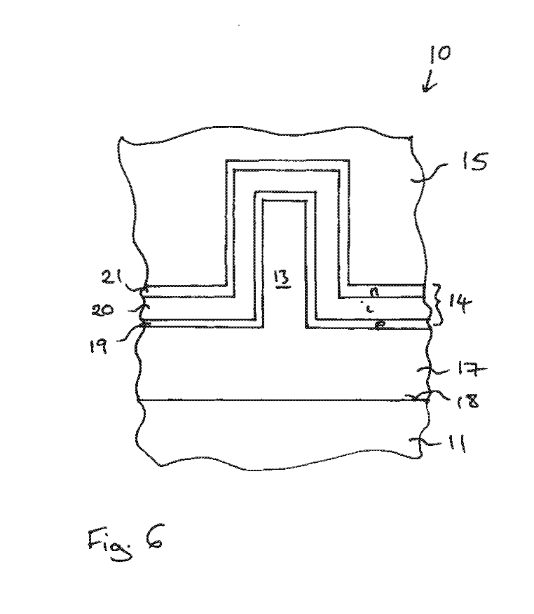

FIG. 5 illustrates the deposition of a second transparent conductive layer onto the substrate of FIG. 4,

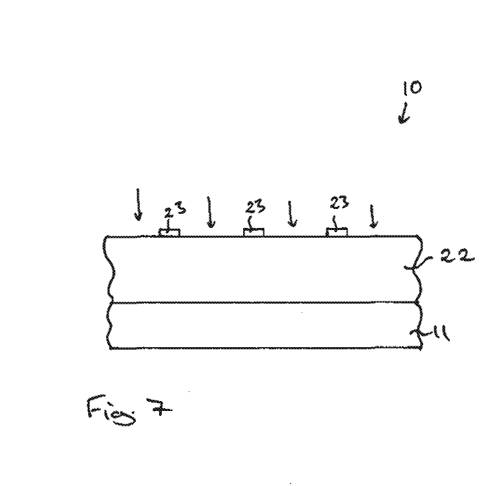

FIG. 6 illustrates the p-i-n structure of the silicon layer of FIGS. 2 to 5,

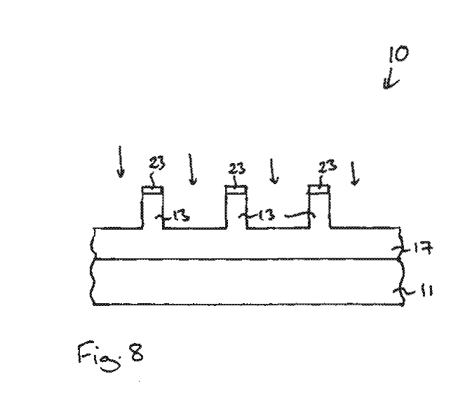

FIG. 7 illustrates a structured resist layer positioned on the first transparent conductive layer. Alternatively, it illustrates a structured metal mask by photolithography or naturally created metal nano-islands.

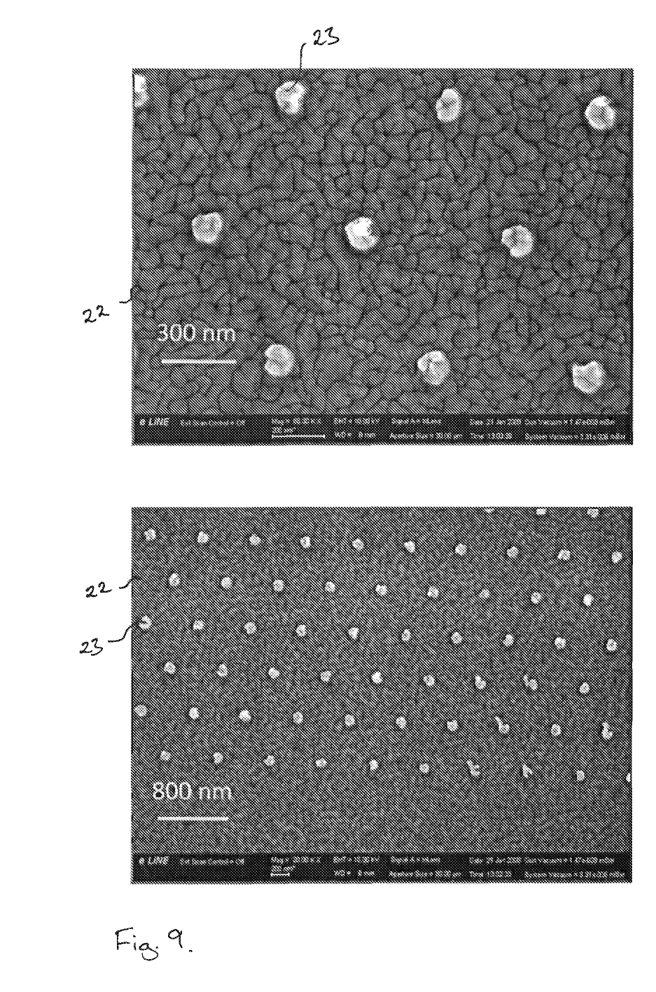

FIG. 8 illustrates the fabrication of a plurality of discrete pillars in the first transparent conductive layer,

FIG. 9 illustrates SEM micrographs of a ZnO precursor layer,

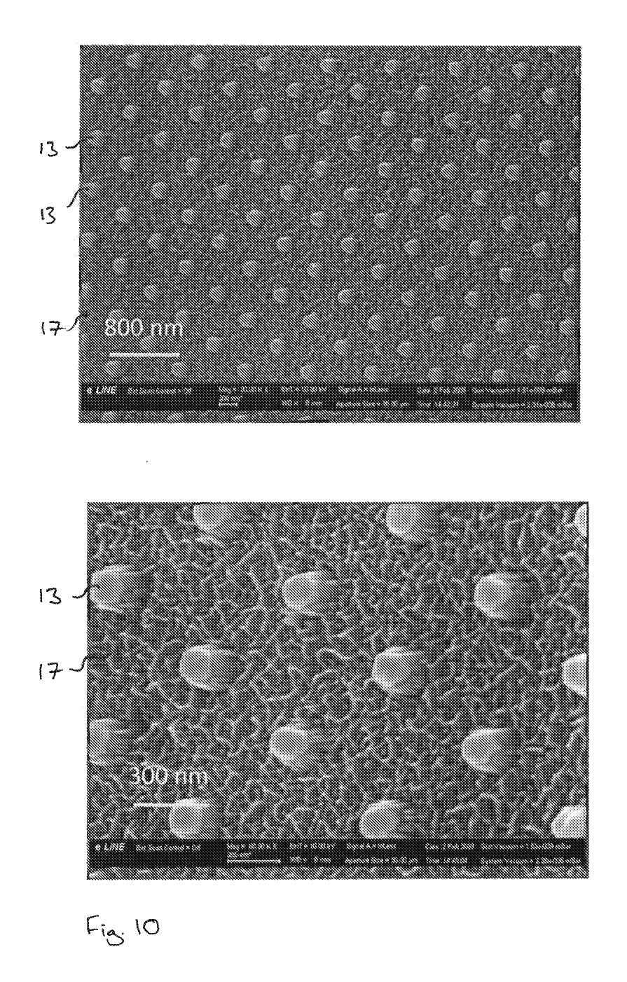

FIG. 10 illustrates SEM Micrographs of the precursor ZnO layer of FIG. 9 after structuring by reactive by ion etching to provide a plurality of ZnO columns,

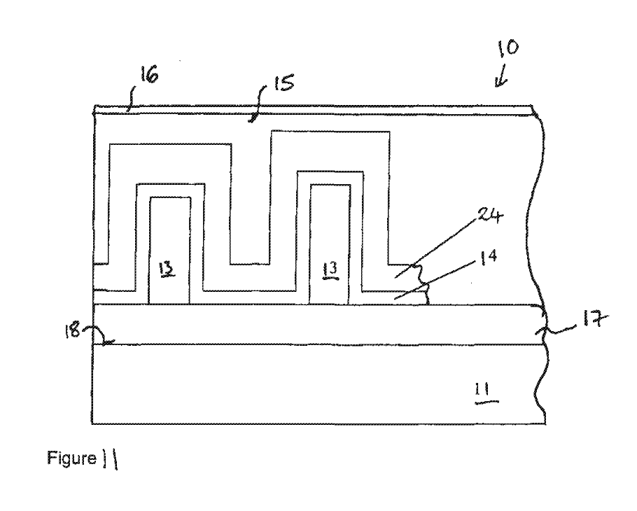

FIG. 11 illustrates a photovoltaic cell including two silicon layers,

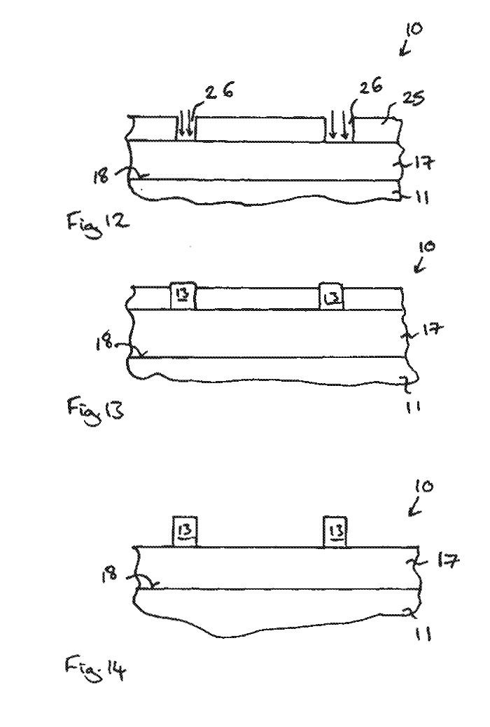

FIG. 12 illustrates a method of depositing a plurality of pillars of a transparent conductive material using a structured resist according to a second embodiment,

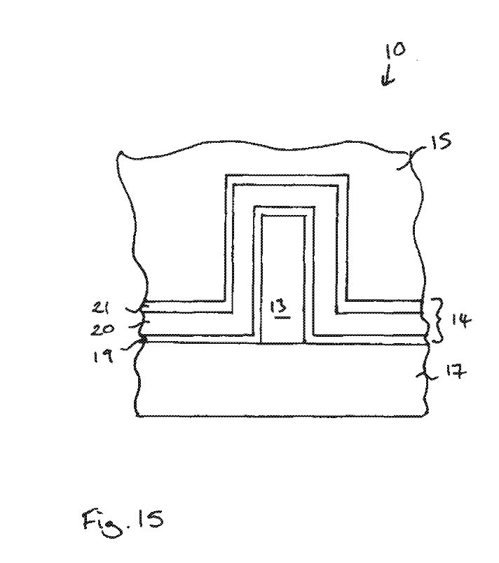

FIG. 13 illustrates depositing transparent conductive material into openings in the structured resist of FIG. 12,

FIG. 14 illustrates the removal of the structured resist to provide a plurality of discrete pillars of the transparent conductive material,

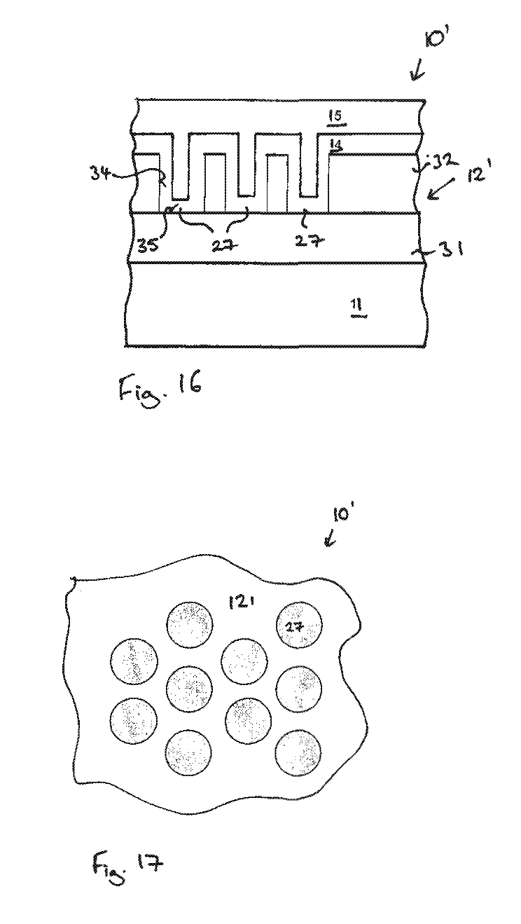

FIG. 15 illustrates a detailed view of a photovoltaic cell fabricated using the arrangement of FIG. 14,

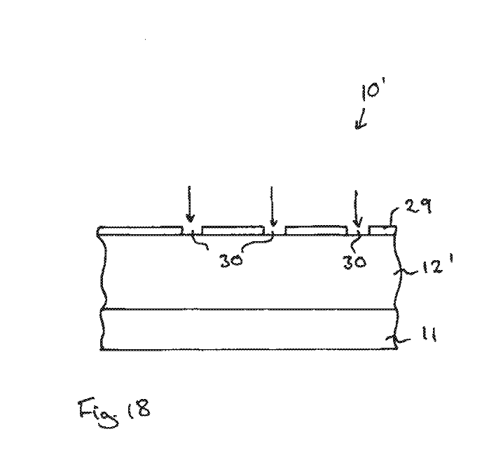

FIG. 16 illustrates a photovoltaic cell according to further embodiment which includes a first transparent conductive layer including a plurality of discrete indentations,

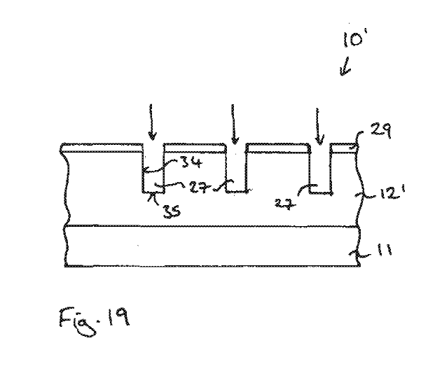

FIG. 17 illustrates a top view of the indentations of FIG. 16,

FIG. 18 illustrates the fabrication of the indentations of FIG. 16 using a mask,

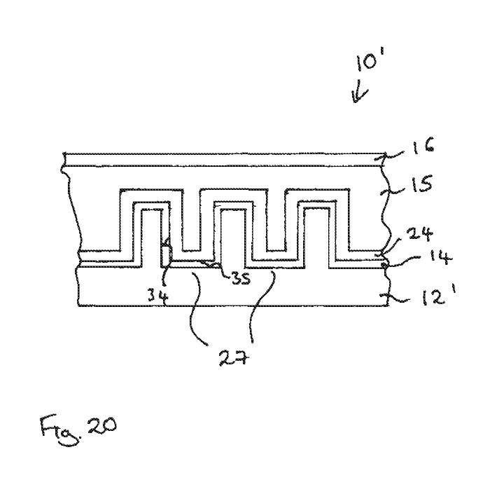

FIG. 19 illustrates the fabrication of the indentations of FIG. 18 by etching,

FIG. 20 illustrates a photovoltaic cell including a first transparent conductive layer including discrete indentations and two silicon absorber layers,

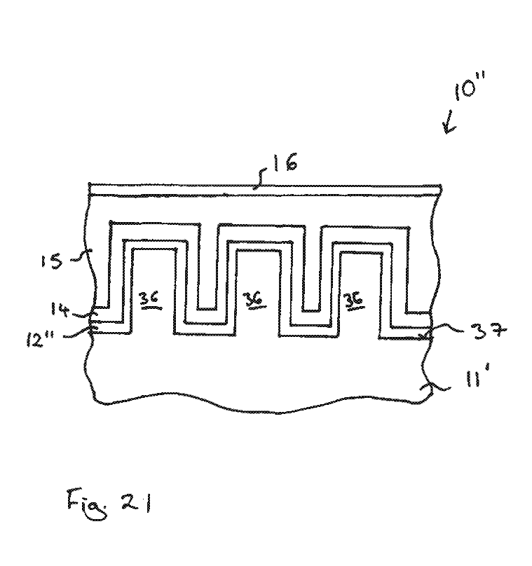

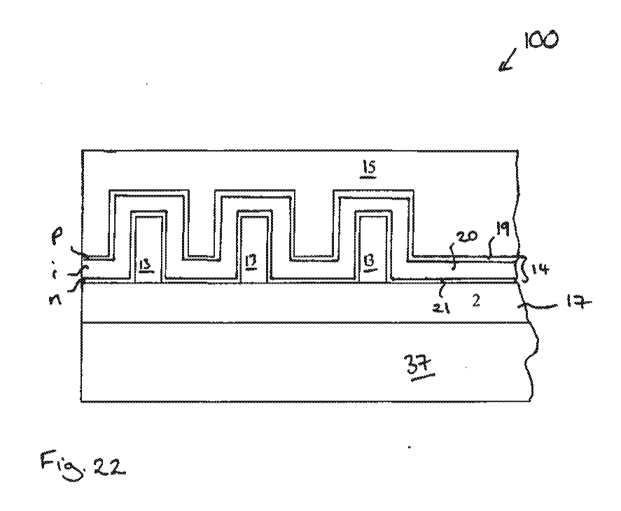

FIG. 21 illustrates a photovoltaic cell according to further embodiment comprising a structured glass substrate, and

FIG. 22 illustrates a photovoltaic cell including a non-transparent substrate.

FIG. 1 illustrates a cross-sectional view of a photovoltaic cell 10 according to a first embodiment. The photovoltaic cell 10 includes a substrate in the form of a glass superstrate 11, a first transparent conductive layer 12 positioned on the superstrate 11, a silicon layer 14 deposited on the first transparent conductive layer 12, a second transparent conductive layer 15 positioned on the silicon layer 14 and a reflective layer 16 positioned on the second transparent conductive layout 15.

The glass superstrate 11 is considered the front of this photovoltaic cell as the photons, in this embodiment solar energy, impinge the glass superstrate 11. The reflective layer 16 is considered the back. The first transparent conductive layer 12 can be termed the front transparent conductive layer and the second transparent conductive layer 15 as the back transparent conductive layer.

The first transparent conductive layer 12 the includes a continuous sub-layer 17 positioned on the superstrate 11 and an ordered array of pillars of a transparent conductive material which extend generally perpendicularly to the major surface 18 of the glass superstrate 11.

As can be seen in the top view of FIG. 2, the pillars 13 are arranged in an approximately hexagonal closed packed array and each has a generally cylindrical form.

The transparent, conductive pillars 13 have a diameter of around 150 nanometres and a height of around 500 nanometres. The transparent conductive material is zinc oxide doped with either aluminium or boron in this embodiment. However, other transparent conductive oxides such as indium tin oxide may also be used.

The silicon layer 14 is deposited conformally over the surface of the sub-layer 17 and pillars 13 of the first transparent conductive layer 12. The silicon layer 14 has a charge separating junction, in this embodiment a p-i-n junction which is illustrated in the detailed view of FIG. 6. The silicon layer may also be described as the absorber layer or the active photovoltaic layer.

In the first embodiment, the second transparent conductive layer 15 fills the spaces between the columnar structures formed by the first transparent oxide layer and silicon layer 14 and extends continuously across the substrate 11 so that its upper surface is generally parallel to the major surface 18 of the substrate 11.

Light impinges the substrate 11 in a perpendicular direction to the major surface of the substrate. Due to the nanoscale pillars 13 of the first transparent conductive layer 12 and the conformal contour of the silicon layer 14, the p-i-n junction as well as the silicon absorber layer has a folded structure. This results in the photovoltaic cell being optically thicker than a planar arrangement of the layers. However, transport of the photogenerated charge between the electrodes the cell is electrically thin as the thickness of the cell overall is not increased. An increased proportion of the photogenerated charge carriers can be collected in p-i-n type structure even in the less advantageous case of the light-soaked amorphous silicon or a higher defect density nano- and microcrystalline silicon.

FIGS. 2 to 6 illustrate the fabrication of the photovoltaic cell of FIG. 1 according to an embodiment.

FIG. 2 illustrates a schematic cross-sectional view of the substrate 11 after the fabrication of the first transparent conductive layer 12 comprising a continuous transparent conductive oxide (TCO) sub-layer 17 positioned on major surface 18 of the substrate 11 and TCO nano-column array 13.

FIG. 3 illustrates a top view of the substrate with a transparent conductive oxide (TCO) sub-layer 12 and TCO array of nanoscale TCO pillars 13. The pillars 13 have a generally cylindrical form and are arranged in an approximately hexagonal closed packed array.

FIG. 4 illustrates a schematic cross-sectional view of the superstrate 11, the TCO sub-layer 12 and TCO nano-column array 13 and further silicon layer 14 deposited conformally on the TCO sub-layer 12 and TCO nano-column array 13. The silicon layer has a p-i-n structure of amorphous silicon illustrated in FIG. 6.

A similar structure with increased height of nanopillars 13 and slightly increased spacing between the nanopillars 13 can be used for tandem or triple junction cells as illustrated in FIG. 11.

FIG. 5 illustrates the structure of FIG. 4 after the deposition of the second transparent conductive layer 15, for example, of a transparent conductive oxide, in particular of ZnO doped with aluminium. The silicon layer 14 is covered with the second transparent conductive layer 15 which acts as a collecting electrode.

FIG. 6 illustrates the p-i-n structure of the silicon layer 14 which provides the active photovoltaic layer or absorber layer of the photovoltaic cell 10. The silicon layer 14 includes three sub-layers. A first sub-layer 19 is deposited conformally on the sub-layer 17 and pillars 13 of the first transparent conductive layer 12. The first sub-layer 19 is positively doped and provides the p-layer of the p-i-n junction. The second sub-layer 20 is intrinsic silicon and is positioned conformally on the first sub-layer 19 to provide the i-layer. The third sub-layer 21 is negatively-doped silicon and is positioned conformally on the intermediate second sub-layer 20 to provide the n-layer of the charge separating junction. The silicon layer may have the structure and be fabricated by a method disclosed in U.S. Pat. No. 6,309,906 which is incorporated herein by reference in its entirety.

The plurality of pillars may be fabricated by selectively removing the uppermost portion of a precursor layer or by selectively depositing a structured layer including the pillars onto a continuous sub-layer.

FIGS. 7 and 8 illustrate the fabrication of a plurality of discrete pillars 13 of aluminium-doped ZnO by selectively removing a precursor layer according to an embodiment.

A precursor film 22 of aluminium-doped ZnO is deposited on the substrate 11. A mask layer is deposited on the precursor layer 22 and structured to provide a plurality of discrete islands 23 corresponding to the desired arrangement of pillars 13. The mask layer 23 comprises a material which is largely or entirely resistant to an etch used to remove the material of the precursor film 22.

The substrate 11 with the precursor layer 22 and structured mask 23 is then subjected to an etching treatment, illustrated schematically by arrows in FIGS. 7 and 8, to remove material of the precursor film 22 in regions not covered by the structured mask 23. The etching is carried out, as illustrated in FIG. 8, until a plurality of discrete pillars 13 of zinc oxide protrude form a continuous sub-layer 17 of zinc oxide and, in particular, until the pillars 13 have the desired height.

In a further embodiment, the doped ZnO layer is covered by a very thin metal layer, then heated up to create metal droplets with a size (diameter) around 100 nm (50-500 nm) and the TCO in between the droplets is etched down to desired depth of 500-1500 nm.

FIGS. 9 and 10 illustrates SEM micrographs of a zinc oxide layer structured by using metal droplets. FIG. 9 illustrates a plurality of Ti/Au islands 23 arranged on the ZnO layer in a hexagonal closed packed ordered array. These islands 23 act as an etch resist and are therefore arranged in the arrangement corresponding to the desired arrangement of the ZnO pillars 13.

The ZnO was then etched away from regions uncovered by the Ti/Au islands to create a plurality of discrete ZnO pillars 13 as illustrated in FIG. 10. A Roth & Rau AK400 and the following etching parameters were used: MW power—2000 W, RF power—100 W, Bias—200 V, H2 flow—100 sccm, CH4 flow—5 sccm, Ar flow—7 sccm, Pressure—0.2 mbar, Etching time—10 min and Achieved temperature—230° C.

Depending on the material used for the first transparent conductive layer, other methods of selectively removing the zinc layer to produce a plurality of discrete pillars may be used, for example, photolithographic techniques or electron beam techniques.

FIG. 11 illustrates a similar structure to that of FIG. 1. However, in this embodiment, the photovoltaic cell includes a tandem or dual junction structure. In this embodiment, the arrangement has an increased height of nanopillars 3 and slightly increased spacing between the nanopillars in comparison to the embodiment of FIG. 1. This design may be used for a tandem junction cell, as is illustrated in FIG. 11, or a triple junction cell.

FIG. 11 illustrates a stage in the production of the photovoltaic cell after deposition of the both the first silicon layer 14 and the second silicon absorber layer 24. The second silicon layer 24 conformally covers the first silicon absorber layer 14. Afterwards, the second, TCO electrode 15 is deposited onto the second silicon layer 24 and the reflector 16 is deposited onto the second transparent conductive layer 15.

If two or more silicon layers are provided, the absorber band gap of the layers may differ in order to further increase the efficiency of the photovoltaic cell.

In one embodiment, the silicon layer comprises a first deposited p-i-n stack with an absorber bandgap larger than the absorber bandgap of a secondly deposited p-i-n stack. For example, the first p-i-n stack may be an amorphous silicon cell and the second, deposited may include a nanocrystalline or microcrystalline silicon p-i-n stack.

In a further embodiment, the silicon layer comprises a first p-i-n stack with a first absorber bandgap, a second p-i-n stack having a second absorber bandgap and a third p-i-n stack having a third absorber bandgap, wherein the second absorber bandgap is larger than the third absorber bandgap and the first absorber bandgap is larger than the second absorber bandgap.

FIGS. 12 to 14 illustrate a further method to fabricate a first transparent conductive layer 12 including a continuous sub-layer 17 and plurality of discrete nanoscale pillars 13. In this embodiment, the continuous sub-layer 17 of the first transparent conductive layer 12 is deposited on the substrate 11 and, afterwards, a resist layer 25 is deposited having a thickness corresponding to the desired height of the pillars 13. The resist layer 25 is then patterned to create a plurality of holes 26 having the lateral arrangement desired for the transparent conductive pillars 13. The continuous sub-layer 17 is exposed in the bottom of these holes 26.

The holes 26 are then filled with transparent conductive material, as illustrated in FIG. 13, and the resist layer 25 removed as illustrated in FIG. 14 to create a first transparent conductive layer 12 including a continuous sub-layer 17 and a plurality of discrete pillars 13 extending generally perpendicular to the major surface 18 of the substrate 11.

The glass superstrate (substrate) 11 is covered with a transparent conductive oxide (TCO) layer 12. TCO nanocolumns (nanopillars, nanorods) 13 made from e.g. ZnO undoped, or doped with aluminum or boron are grown, in a typical geometry shown in FIG. 2. As an example ZnO nanocolumns with a diameter 50-400 nm and length 400-1500 nm are grown essentially homogeneously over the TCO coated superstrate area in a pattern seen from FIG. 2. It means they are essentially equally spaced, with a column to column distance depending on the cell type (single, double or triple p-i-n or p-i-n junctions) and material (amorphous Si, nanocrystalline Si, microcrystalline Si, re-crystallized polycrystalline Si). Typically 400-600 nm are applied for a single amorphous cell and correspondingly more for a multijunction cell. Growth of such aligned ZnO nanorods is described for example in J. Sol-Gel Science Techn. 38 (2006) 79-84 by Y. J. Kim et al.

FIG. 15 illustrates a detailed view of a photovoltaic cell fabricated by depositing zinc oxide pillars 13 onto the zinc oxide sub-layer 17. The active photovoltaic silicon layer 14 includes a conformal three sub-layer p-i-n structure 19, 20, 21 as described in more detail in connection with FIG. 6, and an overlying second transparent conductive layer 15 and reflective layer 16 as described in more detail in connection with FIG. 1.

FIG. 16 illustrates a photovoltaic cell 10′ comprising a first transparent conductive layer 12′ having an alternative structure. In this embodiment, the first transparent conductive layer 12′ includes a plurality of discrete indentations or trenches 27 in its rear surface 28. In this embodiment, the indentations or trenches 27 are cylindrical and have a hexagonal close packed arrangement, as illustrated in the top view of FIG. 17. The indentations 27 can be fabricated by selective removal of the transparent conductive layer 12′ in the positions in which the indentation 27 is desired.

The indentations 27 may be fabricated by etching with the help of a mask 29. This method is illustrated in FIGS. 18 and 19. The mask 29 is used during the etching process to define the array of indentations 27. Alternatively a focused beam technique can be used to selectively remove portions of the transparent conductive layer 12′ without the use of an additional mask to produce a plurality of discrete holes 27 or trenches.

In contrast to the first embodiment, the mask 29 extends across the surface of the first transparent conductive layer 12′ and includes a plurality of circular openings 30 exposing the zinc oxide underneath and therefore enabling the selective removal of the zinc oxide in these exposed regions. The selective removal process can be carried out for a time sufficient to create indentations 27 of the desired depth, as is illustrated in FIG. 19.

In the embodiment illustrated in FIG. 16, the first transparent conductive layer 12′ includes two sub-layers 31, 32. The doping level of the two sub-layers may be different so that the interface 33 between the two sub-layers 31, 32 acts as an etch stop. This can be achieved by adjusting the doping of the upper layer 32 so that it is etched more quickly than the material of the lower layer 31.

In an embodiment, the material of the two sub-layers 31, 32 is different and chosen so that the upper layer 32 is more quickly etched by a selected etchant than the material of the lower layer 31. In an embodiment, the lower layer 31 is SnO2 and the upper layer 32 is ZnO doped with Aluminium or Boron and an etchant of dilute HCl is used to produce a plurality of discrete indentations in the upper ZnO layer 32.

The silicon layer 14 is then conformally deposited onto the first transparent conductive layer 12′ which has been structured to provide a plurality of indentations 27. The side walls 34 and base 35 of the indentations 27 are covered with a layer of silicon. As in previous embodiments, the silicon layer 14 includes three sub-layers 19, 20, 21, the first being positively doped, the second being intrinsic and the third being negatively doped to provide a p-i-n active photovoltaic structure. Since the silicon layer 14 is conformally deposited over the structured first transparent conductive layer, it can be considered to have a folded structure as the junction comprises both vertical and horizontal regions.

FIG. 16 illustrates a similar structure is realized as in FIG. 1, with the help of new “Swiss cheese” design: It starts with the substrate (superstrate) 11, followed by a TCO layer 12 and TCO layer 13. In this layer 13 a holes are etched through, down to the layer 12. The set of holes 27 is closely distributed over the whole area, as it can be seen in FIG. 17. Amorphous Si layer is conformally deposited over. Finally, all is covered by TCO layer 15. Alternatively, TCO2 and TCO3 layers 12, 13 could be one thick TCO layer, followed by an etching process which allows to etch to a certain depth only.

FIG. 17 illustrates a top view of the substrate 11 (superstrate) with the TCO layer 12 covered with TCO layer 13, in which the holes 27 had been etched through the layer 13.

A dual or multi-layer silicon structure can also be deposited on the first transparent conductive layer 12′ having the alternative structure of a plurality of discrete indentations 27, as is illustrated in FIG. 20, rather than discrete pillars 13. Again, a second transparent 15 conductive layer is deposited on the silicon layers 14 followed by a back reflective layer 16.

FIG. 20 illustrates a photovoltaic cell with the substrate (superstrate) 12′, followed by a TCO layers. In this layer 13 is thicker than the layer 13 in FIG. 1 and the holes with a larger diameter than in FIG. 16 are etched through, down to the substrate 12′. The set of holes is closely distributed over the whole area. This design is used for de-position of tandem or triple junction cells. Here a situation is shown after deposition of the first absorber layer 14, followed by deposition of the second absorber 24 and finally coated by the TCO electrode 15, before eventual deposition of the back reflector 16.

FIG. 21 discloses a photovoltaic cell 10″ according to a fourth embodiment. In this embodiment, the glass substrate 11′ is structured to provide a plurality of protrusions 36 in a major surface 37. The protrusions 36 may have a pillar form or may hemi-spherical or pyramidal. The pillars 36 may be cylindrical or have a square or rectangular cross-section. The protrusions 36 in the glass substrate 11′ may also be arranged in an ordered array.

The photovoltaic cell 10″ according to this embodiment includes a first transparent conductive layer 12″ which, as in the previous embodiments, may be a transparent conductive oxide such as zinc oxide doped with aluminium or boron. The first transparent conductive layer 12″ is conformally positioned on the structured surface of the glass substrate 11.

The photovoltaic cell 10″ also includes a silicon layer 14 including a charge separating junction such as a p-n junction or a p-i-n junction. The silicon layer 14 is positioned conformally on the conformal first transparent conductive layer 12″. A second transparent conductive layer 15 is positioned on the silicon layer 14 so as to fill the regions between the covered protrusions 36 and provide the outermost layer which is generally flat. A reflective layer 16 is positioned on the second transparent conductive layer 15

A dual or multilevel silicon layer may also be included in the arrangement of the photovoltaic cell 10″ having a structured glass substrate.

In the above embodiments, the photovoltaic cell 10, 10′, 10″ includes a glass substrate 11, 11′ which is also referred to as a superstrate and a back reflective layer 16. However, the photovoltaic cell may, in alternative embodiments, include a non-transparent substrate 37 such as a metal substrate or polymer substrate. One embodiment is illustrated in FIG. 22.

In these embodiments, the reflective layer is omitted since this function is performed by the substrate 37. In these embodiments, the second transparent conductive layer 15 provides the front of the photovoltaic cell 100 and is impinged by photons and the substrate 37 is arranged at the back.

In these embodiments, the order of the positively charged 19 and negatively charged silicon sub-layers 21 is reversed compared with the order of these layers in photovoltaic cells 10, 10′, 10″ including a glass substrate 11. The n-layer 21 is deposited on the first transparent conductive layer 17, the intrinsic layer 20 on the n-layer 21 and the p-layer 19 on the intrinsic layer 20. The p-layer 19 lies towards the front surface of the photovoltaic cell 100 as in the embodiments including a glass substrate.

The embodiments described above can be realized with substrates of small size as well as with substrates of >1 mm².

The similar TCO nanostructure can be realized also in the substrate configuration, using a metal or plastic foil.

The TCO nanostructure is not limited to the growth of ZnO nanorods (nanopillars, nanocolumns), the manufacturing method is not restricted to selective etching of a TCO layer. A similar charge collecting nanostructured electrode can be directly etched into a glass superstrate or embossed in the plastic or metallic substrate. In this case a conformal coating of this nanostructured superstrate or substrate by smooth or nano-rough TCO creates a similarly functioning charge collecting electrode.

Further, textured glass can be manufactured by using photolithography. The height and pitch of the structures can be varied over a wide range deposition of solar cells will take place on top of these structures.

Beside the geometrical structure of rods also nano structures of cones, pyramids or hemispheres are applicable. The top points of these structures may be flattened. The latter may be easier to manufacture and favor an improved conformal deposited layer.

In a further embodiment, contrary to the above described ZnO nanorods or similar TCO nanostructure, a TCO layer in a form of porous membrane is used. It means that typically circular pores (holes of diameter around 500 nm) are etched through (less doped) TCO layer 13 (of a thickness in the range 300-1000 nm) down to another TCO layer 12 which satisfies electrical conductivity for good collection of photogenerated carriers. Such “Swiss cheese” like substrate or superstrate is used for conformal de-position of p-i-n structure of the absorber, as for example amorphous silicon.

Then the p-i-n structure of the absorber, as for example amorphous silicon, is deposited on the superstrate with a typical thickness of the absorber being 150-200 nm. Again, this range is not intended to be limiting just to that thickness range. Thickness will vary because of the not perfectly homogeneous conformal coverage of nanopillars or holes in any deposition process. There is no need for a regular shape of the hole, hole can be of cylinder, barrel, conus or other type.

In a tandem cell, the p-i-n amorphous silicon structure is deposited first and then another p-i-n structure made from a lower bandgap material, as the microcrystalline or nanocrystal line silicon or silicon-germanium alloy is deposited. The holes as shown in FIG. 11 etched through TCO layer 13 have a larger diameter (at least around 1 to around 2 micrometers, than in the case of amorphous silicon single junction cell and the thickness of TCO layer 13 can be larger, around 0.5 to around 2 micrometers, than in the case of amorphous silicon solar cell.

The single junction structure of FIG. 4 (absorber being amorphous, nanocrystalline or microcrystalline Si or recrystallized Si) is then covered with the second charge collecting electrode 15, made again of TCO or combination of TCO/metal deposited over the folded absorber layer(s) 14. This is shown in FIG. 5. In the case using just TCO, a back reflector 16 is added to this solar cell structure.

A back reflecting layer 16 comprising a white pigmented dielectric reflective media, as described for example in U.S. patent application Ser. No. 11/044,118 can be used. The Back reflecting layer can be made also of metal as aluminum or silver.

This invention is not limited to a single junction cells but it can be extended to tandem and triple junction cells. Schematic drawing of realization of tandem amorphous/micro-crystalline cell is shown in FIGS. 11 and 20 is then covered with the second charge collecting electrode, made again of TCO or combination of metal/TCO deposited over the folded absorber layers and filling the nanospace in between. In the case of simple TCO layer the back reflecting layer comprising a white pigmented dielectric reflective media should be used.

A thin film silicon, single or multijunction solar cell having a nanostructured substrate or superstrate including an electrode made of transparent conductive oxide (TCO) which forms an array of nanopillars and over these nanopillars the thin film silicon, like amorphous or nano- or micro-crystalline silicon is deposited by plasma enhanced chemical vapor deposition in a such way that for the light coming in perpendicular direction to the substrate or superstrate the cell is optically thick but for a transport of the photogenerated charge between the electrodes the cell is electrically thin so practically all photogenerated charge carriers can be collected in p-i-n type structure even in the less advantageous case of the light-soaked amorphous silicon or a higher defect density nano- and microcrystalline silicon, the second charge collecting electrode being again TCO or combination of metal/TCO deposited over the folded absorber layer(s) and filling the nanospace in between.

In the additional form of realization, a Swiss cheese TCO structure is provided.

1. A photovoltaic cell comprising:
a substrate carrier;
a first transparent conductive layer positioned on the substrate carrier comprising a plurality of discrete transparent conductive protruding regions or a plurality of discrete indentations,
a silicon layer comprising a charge separating junction covering the first transparent conductive layer and the plurality of discrete transparent conductive protruding regions or the plurality of discrete indentations, and
a second transparent conductive layer positioned on the silicon layer.

2. The photovoltaic cell according to claim 1, wherein
the charge separating junction has a contour which is adapted to the contour of the first transparent conductive layer.

3. The photovoltaic cell according to claim 1 or claim 2, wherein
the charge separating junction comprises alternately arranged generally vertical and generally horizontal regions.

4. The photovoltaic cell according to one of the preceding claims,
wherein the silicon layer is positioned conformally on the first transparent conductive layer.

5. The photovoltaic cell according to one of the preceding claims, wherein
the second transparent conductive layer is positioned conformally on the silicon layer.

6. The photovoltaic cell according to one of the preceding claims, wherein
the plurality of discrete transparent conductive protruding regions or the plurality of discrete indentations are on the borderline of nanoscale to microscale.

7. The photovoltaic cell according to one of the preceding claims,
wherein the plurality of transparent conductive protruding regions or indentations extend generally perpendicular to a major plane of the substrate carrier.

8. The photovoltaic cell according to one of the preceding claims,
wherein the plurality of transparent conductive protruding regions or the plurality of indentations are arranged in an approximately ordered array.

9. The photovoltaic cell according to claim 8,
wherein the approximately ordered array has a closely hexagonal closed packed or random arrangement.

10. The photovoltaic cell according to one of the preceding claims,
wherein the transparent conductive nanoscale protruding regions or the microscale plurality of indentations each have the form of one of more of a pillar, a cone or a pyramid or a hemisphere.

11. The photovoltaic cell according to one of the preceding claims,
wherein the substrate carrier comprises a plurality of nanoscale protruding regions, the first transparent conductive layer is positioned conformally on the substrate carrier and the silicon layer is positioned conformally on the first transparent conductive layer.

12. The photovoltaic cell according to one of the preceding claims,
wherein the second transparent conductive layer fills regions between the protruding regions of the silicon layer.

13. The photovoltaic cell according to one of preceding claims,
wherein the charge separating junction is one of a pn junction and a pin junction.

14. The photovoltaic cell according to one of the preceding claims,
wherein the silicon layer comprises a p-type semiconductor layer, an intrinsic layer and a n-type semiconductor layer of amorphous, nanocrystalline, microcrystalline or recrystallized polycrystalline silicon.

15. The photovoltaic cell according to one of the preceding claims,
wherein the silicon layer comprises a first deposited p-i-n stack with an absorber bandgap larger than the absorber bandgap of a secondly deposited p-i-n stack.

16. The photovoltaic cell according to claim 15, wherein
the first p-i-n stack comprises amorphous silicon and the second p-i-n stack comprises nanocrystalline or microcrystalline silicon.

17. The photovoltaic cell according to one of claims 1 to 14,
wherein the silicon layer comprises a first p-i-n stack with a first absorber bandgap, a second p-i-n stack having a second absorber bandgap and a third p-i-n stack having a third absorber bandgap,
wherein the second absorber bandgap is larger than the third absorber bandgap and the first absorber bandgap is larger than the second absorber bandgap.

18. The photovoltaic cell according to one of the preceding claims,
wherein the p-type semiconductor layer is positioned on the first transparent conductive layer, the intrinsic layer is positioned on the p-type semiconductor layer and the n-type semiconductor layer is positioned on the intrinsic layer.

19. The photovoltaic cell according to one of the preceding claims further comprising a reflective layer positioned on the second transparent conductive layer.

20. The photovoltaic cell according to claim 19,
wherein the reflective layer comprises a white pigmented dielectric reflective media.

21. The photovoltaic cell according to one of the preceding claims,
wherein the substrate carrier is glass.

22. The photovoltaic cell according to one of claims 1 to 16,
wherein the n-type semiconductor layer is positioned on the substrate, the intrinsic layer is positioned on the n-type semiconductor layer and the p-type semiconductor layer is positioned on the intrinsic layer.

23. The photovoltaic cell according to claim 22,
wherein the substrate comprises metal or plastic.

24. The photovoltaic cell according to claim 22 or claim 23 further comprising a conductive layer comprising metal is positioned on the substrate carrier.

25. Method of fabricating a photovoltaic cell comprising:
providing a substrate carrier,
depositing a first transparent conductive layer onto the substrate carrier,
forming a plurality of discrete transparent conductive protruding regions on the first transparent conductive layer or forming a plurality of discrete indentations in the first transparent conductive layer,
depositing a silicon layer comprising a charge separating junction onto the first transparent conductive layer and the plurality of protruding regions or the plurality of indentations,
depositing a second transparent conductive layer on the silicon layer.

26. Method according to claim 25, wherein
a closed layer of a transparent conductive material is deposited and selectively removed to produce the plurality of discrete transparent conductive protrusions or the plurality of discrete indentations.

27. Method according to claim 25 or claim 26, wherein
a plurality of discrete metal islands are deposited on the closed layer and regions outside of the metal islands are removed by selective etching to produce a plurality of protruding regions of transparent conductive material.

28. Method according to claim 25 or claim 26, wherein
a patterned resist layer is produced on the closed layer and discrete indentations etched in the closed transparent conductive layer.

29. Method according to claim 27 or claim 28, wherein
the depth of the indentations or the height of the protruding regions is controlled by the etching time.

30. Method according to one of claims 25 to 29, wherein
a first closed layer of a first transparent conductive material having a first composition is deposited and a second closed layer of transparent conductive material having a second composition is deposited, the second closed layer is selectively etched away until the boundary between the first and second layers is reached.

31. Method according to one of claims 24 to 30, wherein
the first transparent conductive layer is structured by reactive ion etching to produce the plurality of discrete protruding regions of a transparent conductive material or the plurality of discrete indentations.

32. Method according to claim 25 or claim 26, wherein
the first transparent conductive layer is structured by electron beam lithography to produce the plurality of discrete protruding regions of a transparent conductive material or the plurality of discrete indentations.

33. Method according to one of claims 25 to 32, wherein
the plurality of protruding regions or the plurality of indentations have the form of one or more of a pillar, a pyramid, a hemisphere or a cone.

34. Method according to one of claims 25 to 33, wherein
the silicon layer is deposited conformally onto the first transparent conductive layer and the plurality of protruding regions or the plurality of indentations.

35. Method according to one of claims 25 to 34, wherein
the second transparent conductive layer is deposited conformally onto the silicon layer.

36. Method according to one of claims 25 to 35, wherein
the second transparent conductive layer fills regions between adjacent protruding regions or fills the indentations.

37. Method according to one of claims 25 to 36, wherein
three sub-layers are deposited to form the silicon layer and a p-i-n or n-i-p charge separating junction.

38. Method according to claim 25,
wherein the substrate carrier is structured to produce a plurality of discrete protruding regions or a plurality of discrete indentations.

39. Method according to claim 38,
wherein the first transparent conductive layer is deposited conformally on the substrate carrier, the silicon layer is deposited conformally on the first transparent conductive layer.

40. Method according to one of claims 25 to 39 wherein the substrate carrier is glass and a further reflective layer is deposited onto the second transparent conductive layer.
